(19) United States
(12) Patent Application Publication
(10) Pub. No.: US 2025/0079331 A1
(43) Pub. Date: Mar. 6, 2025

(54) METHOD OF MANUFACTURING WAFER

(71) Applicant: DISCO CORPORATION, Tokyo (JP)

(72) Inventors: Nobuki KAKIUCHI, Tokyo (JP); Tomoki YOSHINO, Tokyo (JP); Kazuya HIRATA, Tokyo (JP)

(21) Appl. No.: 18/812,168

(22) Filed: Aug. 22, 2024

(30) Foreign Application Priority Data
Aug. 28, 2023 (JP) 2023-137868

(51) Int. Cl. H01L 23/544; B23K 26/00; B23K 26/364; B23K 101/40; H01L 21/66

(52) U.S. Cl. CPC H01L 23/544; B23K 26/0093; B23K 26/364; H01L 22/12; B23K 2101/40; H01L 2223/54493

(57) ABSTRACT

A method of manufacturing a wafer from an ingot includes positioning the focused spot of a laser beam transmittable through the ingot in the ingot, applying the laser beam to the ingot to form a separation layer in the ingot while moving the ingot and the focused spot relatively to each other, applying external forces to the ingot to sever the ingot along the separation layer that acts as a separation initiating point, thereby separating a piece of the ingot as the wafer off from the ingot, and forming a mark indicative of the crystal orientation of the material of the wafer on the wafer.

### BACKGROUND OF THE INVENTION

### Field of the Invention

The present invention relates to a method of manufacturing a wafer shaped as a circular plate from a cylindrical ingot.

### Description of the Related Art

Devices such as integrated circuits (ICs), large-scale-integration (LSI) circuits, or light-emitting diodes (LEDs) are formed in arrays on a face side of a wafer made of a semiconductor material, and then the wafer is divided along side edges of the devices into device chips that will be incorporated in electronic appliances. For manufacturing a wafer shaped as a circular plate, a mass called an ingot fabricated by way of crystal growth is ground into a cylindrical shape. Then, the ingot is sliced across its longitudinal axis by a wire saw, producing a circular wafer (see JP 2001-272359A). However, the cutting process using the wire saw is problematic in that when the ingot is sliced by the wire saw, the amount of material of the ingot lost as saw dust is so large that the number of wafers obtained from the ingot is unduly small compared with a size of the ingot. Another problem with the wire saw is that when the ingot is sliced by the wire saw, the wire saw tends to leave undulations on the face and reverse sides of a wafer. In order to remove the undulations, the face and reverse sides of the wafer need to be polished, resulting in a further loss of the material. Consequently, the cutting process using the wire saw is liable to result in low productivity.

There has been known in the art a process that uses a laser beam having a wavelength transmittable through the material of an ingot, i.e., a wavelength transmittable through a semiconductor material, as a process of cutting an ingot. According to this process, a separation surface is hypothetically established in an ingot at a predetermined depth from a surface of the ingot, and a laser beam is applied to the ingot while positioning its focused spot on the separation surface and scans the ingot to move the focused spot along the separation surface, forming separation initiating points, i.e., separation layers, in the ingot, the separation initiating points including modified layers and cracks developed from the modified layers. Then, the ingot is severed along the separation initiating points, i.e., the separation layers, separating off a wafer from the ingot (see JP 2016-127186A).

A wafer has on its outer circumferential edge a mark called an orientation flat or a notch indicative of a crystal orientation of the material of the wafer. The crystal orientation of the material of the wafer is specified on an ingot from which the wafer is to be separated. For example, the crystal orientation of the material of the ingot is specified by way of X-ray diffraction (XRD), and a mark such as an orientation flat indicative of the specified crystal orientation is formed on the ingot (see JP 2005-219506A). When the ingot is then severed along the separation layers, a wafer with a mark indicative of its crystal orientation is separated from the ingot.

### SUMMARY OF THE INVENTION

An ingot from which to manufacture wafers is much larger than the wafers. When the ingot is processed in a step of grinding the ingot into a cylindrical shape and a step of forming a mark such as an orientation flat on the ingot, the ingot loses a large amount of its material. In these steps, the ingot has to be processed under relatively large processing loads and requires dedicated large-scale processing facilities. Therefore, it has been highly costly to process the ingot. For these reasons, there is room for improvement in processes of manufacturing wafers, and demands exist in the art for a further increase in the productivity of the processes of manufacturing wafers.

It is therefore an object of the present invention to provide a method of manufacturing a wafer on which to construct devices, with high productivity.

In accordance with an aspect of the present invention, there is provided a method of manufacturing a wafer from an ingot. The method includes a separation layer forming step of positioning the focused spot of a laser beam transmittable through the ingot in the ingot and applying the laser beam to the ingot to form a separation layer in the ingot while moving the ingot and the focused spot relatively to each other, after the separation layer forming step, a separating step of applying external forces to the ingot to sever the ingot along the separation layer that acts as a separation initiating point, thereby separating a piece of the ingot as the wafer off from the ingot, and after the separating step, a mark forming step of forming a mark indicative of a crystal orientation of a material of the wafer on the wafer.

Preferably, the method further incudes before the separating step, a crystal orientation measuring step of measuring characteristics with respect to the crystal orientation of the material, in which the mark forming step includes determining a position and a shape on the wafer of the mark formed on the wafer in the mark forming step, on the basis of the characteristics measured in the crystal orientation measuring step.

Preferably, the mark forming step includes processing an outer circumferential portion of the wafer with a laser beam to form the mark on the wafer.

In accordance with another aspect of the present invention, there is provided a method of manufacturing a wafer from an ingot. The method includes a separation layer forming step of positioning the focused spot of a laser beam transmittable through the ingot in the ingot and applying the laser beam to the ingot to form a separation layer in the ingot while moving the ingot and the focused spot relatively to each other, after the separation layer forming step, a separating step of applying external forces to the ingot to sever the ingot along the separation layer that acts as a separation initiating point, thereby separating a piece of the ingot as the wafer off from the ingot, and after the separating step, an outer form shaping step of shaping an outer form of the wafer.

Preferably, the method further includes, after the separating step, a mark forming step of forming a mark indicative of a crystal orientation of the material of the wafer on the wafer.

Preferably, the method further includes, before the separating step, a crystal orientation measuring step of measuring characteristics with respect to the crystal orientation of the material, in which the mark forming step includes determining a position and a shape on the wafer of the mark formed on the wafer in the mark forming step, on the basis of the characteristics measured in the crystal orientation measuring step.

Preferably, the method further includes, after the separating step but before the outer form shaping step, an inspecting step of inspecting the wafer to ascertain whether the wafer contains a crystal defect or not and to detect a position of a crystal defect, if any, in which if it is ascertained that the wafer has the crystal defect in the inspecting step, the outer form shaping step includes removing the crystal defect by shaping the outer form of the wafer.

According to the present invention, the focused spot of the laser beam is positioned in the ingot, and the laser beam is applied to the ingot to form the separation layer in the ingot. Thereafter, the ingot is severed along the separation layer, separating off a piece of the ingot as the wafer from the ingot. Thereafter, a mark indicative of the crystal orientation of the material of the wafer is formed on the wafer, and the outer form of the wafer is shaped. When the wafer is processed, it undergoes a smaller processing load and requires a smaller-scale processing facility than when the ingot is processed. The processing facility does not need to be a dedicated one, and may be a general-purpose processing facility. Moreover, detailed processing conditions may be selected for appropriately processing the wafer to a nicety. Therefore, the cost required to manufacture the wafer is reduced, and the wafer is manufactured with high quality and high productivity.

According to the present invention, therefore, there is provided a method of manufacturing a wafer having devices constructed thereon with high productivity.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1A is a perspective view schematically illustrating an ingot;

FIG. 1B is a vertical cross-sectional view schematically illustrating the ingot;

FIG. 2 is a perspective view schematically illustrating the ingot in a crystal orientation measuring step;

FIG. 3 is a plan view schematically illustrating the ingot in the crystal orientation measuring step;

FIGS. 4A, 4B, 4C, 4D, and 4E are plan views schematically illustrating reduced-strength regions;

FIG. 5 is a side-elevational view, partly in vertical cross section, schematically illustrating an optical system of a laser beam applying unit of a laser processing apparatus;

FIG. 6A is a perspective view schematically illustrating the ingot in a separation layer forming step;

FIG. 6B is a fragmentary vertical cross-sectional view schematically illustrating the ingot in the separation layer forming step;

FIG. 7 is a plan view schematically illustrating the ingot with separation layers formed therein;

FIG. 8A is a vertical cross-sectional view, partly in side elevation, schematically illustrating the ingot in a first stage of a separating step;

FIG. 8B is a vertical cross-sectional view, partly in side elevation, schematically illustrating the ingot in a second stage of the separating step;

FIG. 9A is a perspective view schematically illustrating a wafer whose outer form has not yet been shaped;

FIG. 9B is a plan view schematically illustrating the wafer whose outer form has not yet been shaped;

FIG. 10A is a plan view schematically illustrating a wafer on which marks have not yet been formed;

FIG. 10B is a plan view schematically illustrating the wafer with the marks formed thereon;

FIG. 11 is a plan view schematically illustrating a wafer with marks according to a modification formed thereon;

FIG. 12A is a flowchart of the sequence of steps of a method of manufacturing a wafer according to an embodiment of the present invention; and

FIG. 12B is a flowchart of the sequence of steps of a method of manufacturing a wafer according to another embodiment of the present invention.

### DETAILED DESCRIPTION OF THE PREFERRED EMBODIMENTS

Methods of manufacturing a wafer, also referred to as “wafer manufacturing methods,” according to preferred embodiments of the present invention will be described below with reference to the accompanying drawings. The wafer manufacturing methods manufacture wafers for use in the fabrication of devices to be incorporated in electronic appliances. A wafer manufactured by any of the wafer manufacturing methods includes a substrate shaped as a circular plate made of a material such as silicon (Si), silicon carbide (SiC), gallium nitride (GaN), gallium arsenide (GaAs), or any of other semiconductors. A plurality of devices such as ICs, LSI circuits, or LEDs, for example, are constructed in an array of areas demarcated on the face side of the wafer, and then the wafer is divided along projected dicing lines extending between the areas into individual device chips. The wafer shaped as a circular plate is manufactured as a slice cut from a cylindrical ingot.

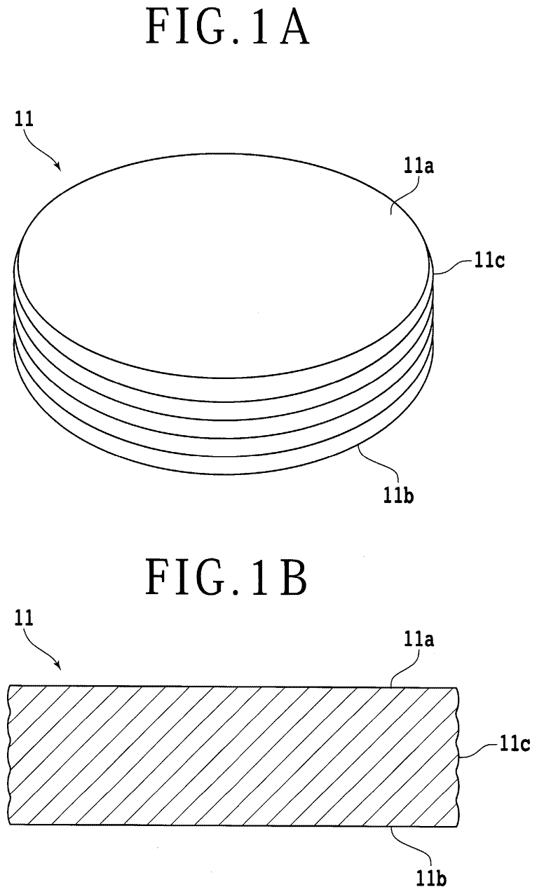

Recently, SiC wafers have been focused upon as wafers to be used in the fabrication of device chips having devices such as power devices and LSI circuits that can operate at high temperatures and have high withstand voltages. A SiC wafer that is shaped as a circular plate is manufactured as a slice cut from a cylindrical ingot, e.g., a hexagonal monocrystalline ingot, 11 (see FIG. 1A, for example) made of SiC. The ingot 11 of SiC is produced by way of epitaxial growth such that the c-axis of monocrystalline SiC is slightly inclined to a line normal to a face side 11a and a reverse side 11b of the ingot 11. An angle, i.e., an off-angle, formed between the c-axis and the line normal to the face side 11a and the reverse side 11b is in the range from 1° to 6°, and is typically 4°.

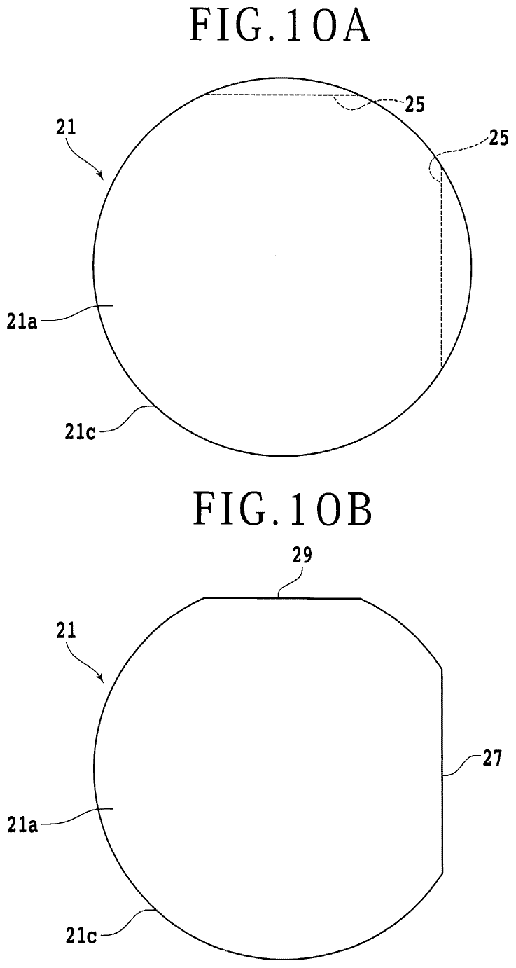

FIG. 1A schematically illustrates the ingot 11 in perspective. FIG. 1B schematically illustrates the ingot 11 in vertical cross section. The ingot 11 that has been fabricated in a crystal growth step has miniscule surface irregularities on an outer circumferential surface 11c whose outer form has not yet been shaped, as illustrated in FIGS. 1A and 1B. Generally, the outer circumferential surface 11c of the ingot 11 from the crystal growth step is ground to turn the ingot 11 into a cylindrical shape. A mass of SiC before and after it is ground into a cylindrical shape is herein referred to as an “ingot.” The ingot 11 that has been ground into a cylindrical shape is then severed across its longitudinal axis, separating off a SiC wafer from the ingot 11. FIG. 10B schematically illustrates, in plan, a wafer 21 that has been manufactured by the wafer manufacturing method according to one of the preferred embodiments of the present invention.

In a case where the wafer 21 is made of monocrystalline SiC, two marks indicative of the crystal orientation of the monocrystalline SiC are formed on the wafer 21. Specifically, a first orientation flat 27 and a second orientation flat 29 lying perpendicularly to the first orientation flat 27 are formed as the respective two marks on an outer circumferential edge 21c of the wafer 21. The first orientation flat 27 is longer than the second orientation flat 29. Generally, the first orientation flat 27, also referred to as an “primary orientation flat,” extends along a particular direction that is advantageous for the mobility of electrons at the time semiconductor devices such as metal-oxide-semiconductor field-effect transistors (MOSFETs) are constructed on monocrystalline SiC. The second orientation flat 29, also referred to as a “secondary orientation flat,” extends along a direction in which the c-axis is inclined to a line normal to a face side 21a and a reverse side 21b of the wafer 21, i.e., a direction in which the off-angle is formed.

For severing the ingot 11, a laser beam having a wavelength transmittable through the material, i.e., Sic, of the ingot 11 is applied to the ingot 11. Specifically, the focused spot of the laser beam is positioned at a predetermined depth in the ingot 11 that corresponds to the thickness of the wafer 21 to be manufactured from the ingot 11, and the laser beam is applied to the ingot 11 while the focused spot is being moved horizontally relatively to the ingot 11. The laser beam thus applied forms a separation layer, i.e., a modified layer, acting as peel-off initiating points, within the ingot 11. Then, the ingot 11 is severed along the separation layer, i.e., the modified layer, separating off a piece of the ingot 11 as the wafer 21 from the ingot 11.

Heretofore, it has been the usual practice to measure the crystal orientation of the material of an ingot 11 and form marks such as a notch and an orientation flat indicative of the crystal orientation on the ingot 11. Since a wafer 21 cut off from the ingot bears the marks, the crystal orientation of the wafer 21 can be confirmed from the marks. However, as described above, the ingot 11 loses a large amount of its material in a step of grinding the ingot 11 into a cylindrical shape and a step of forming a mark such as an orientation flat on the ingot 11. In these steps, the ingot has to be processed under relatively large processing loads and requires dedicated large-scale processing facilities. Therefore, it has been highly costly to process the ingot 21, and the processes of manufacturing wafers from ingots have been low in productivity.

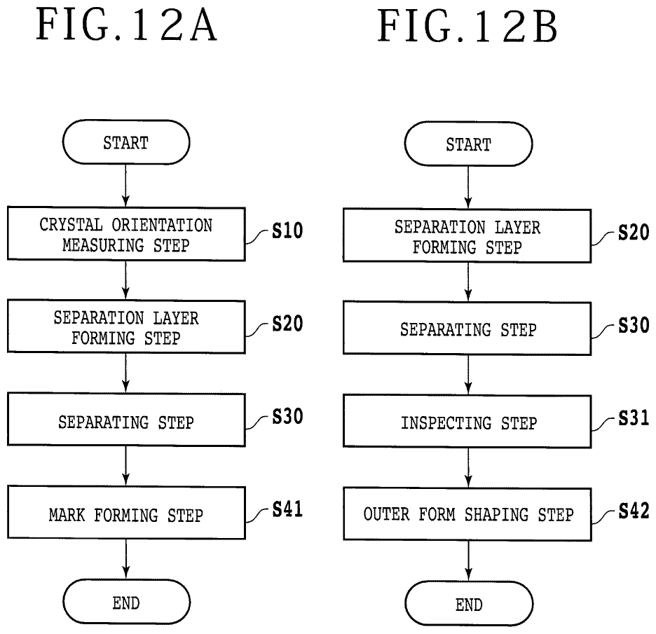

In the wafer manufacturing methods according to the embodiments of the present invention, the laser beam is applied to the ingot 11 while the focused spot of the laser beam is being positioned in the ingot 11, forming a separation layer in the ingot 11. Then, the ingot 11 is severed along the separation layer, separating off the wafer 21 from the ingot 11. Thereafter, a mark indicative of the crystal orientation of the wafer 21 is formed on the wafer 21, and/or the outer form of the wafer 21 is shaped. When the wafer 21 is processed, it undergoes a smaller processing load and requires a smaller-scale processing facility than when the ingot 11 is processed. The processing facility does not need to be a dedicated one and may be a general-purpose processing facility. Moreover, detailed processing conditions may be selected for appropriately processing the wafer 21 to a nicety. Therefore, the cost required to manufacture the wafer 21 is reduced and the wafer 21 is manufactured with high quality and high productivity. The methods of manufacturing the wafer 21 from the ingot 11 according to the preferred embodiments of the present invention will be described briefly below with reference to FIGS. 12A and 12B.

In the wafer manufacturing methods, separation layer forming step S20 is carried out to form a separation layer within the ingot 11, and then separating step S30 is carried out to sever the ingot 11 along the separation layer to separate off the wafer 21 as a severed piece from the ingot 11. After separating step S30, one of or both of mark forming step S41 for forming marks representing the crystal orientation of the material of the wafer 21 on the wafer 21 and outer form shaping step S42 for shaping the outer form of the wafer 21 are carried out.

Each of the steps described above and other steps of the wafer manufacturing methods will be described in detail below. FIG. 12A is a flowchart of the sequence of steps, including mark forming step S41, of the wafer manufacturing method according to one of the embodiments of the present invention, and FIG. 12B is a flowchart of the sequence of steps, including outer form shaping step S42, of the wafer manufacturing method according to the other embodiment of the present invention. The wafer manufacturing method that includes mark forming step S41 should preferably include crystal orientation measuring step S10 for measuring characteristics with respect to the crystal orientation of the material, prior to separating step S30 and more preferably prior to separation layer forming step S20. The material described above refers to both the material of the ingot 11 and the material of the wafer 21 manufactured from the ingot 11.

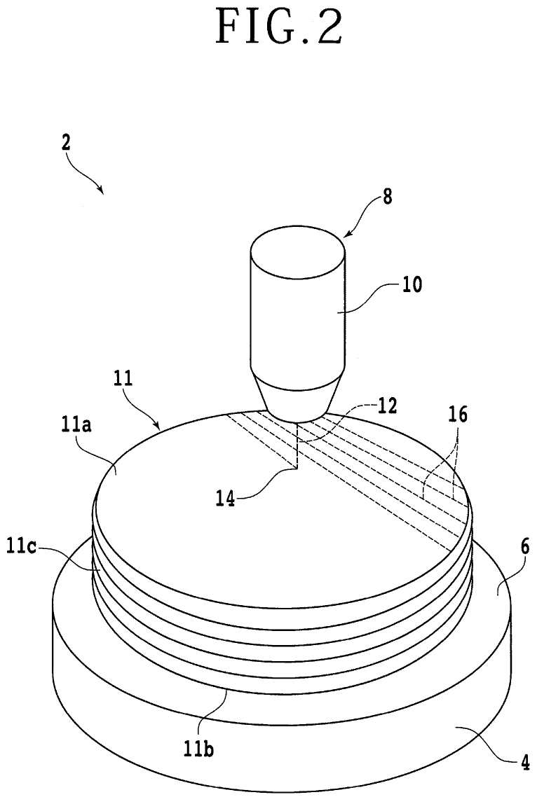

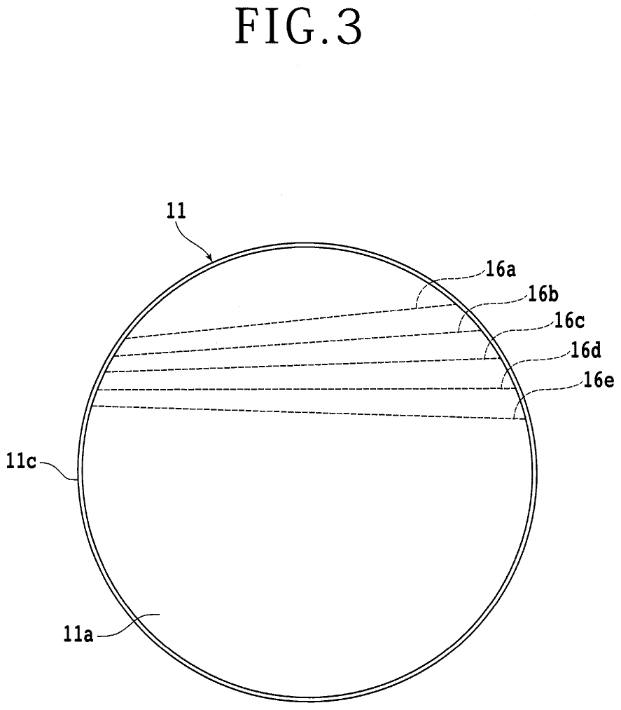

Details of crystal orientation measuring step S10 will be described below. In crystal orientation measuring step S10, characteristics with respect to the crystal orientation of the material of the ingot 11 are measured by a known process such as X-ray diffraction. The measured characteristics with respect to the crystal orientation of the material of the ingot 11 are used when marks indicative of the crystal orientation of the material are formed on the wafer 21 subsequently in mark forming step S41. However, for measuring the ingot 11 by way of X-ray diffraction, a relatively large-scale and expensive measuring apparatus would be needed, resulting in a reduction of the productivity of the wafer 21. In crystal orientation measuring step S10 in the method of manufacturing a wafer according to the present embodiment, characteristics with respect to the crystal orientation of the material of the ingot 11 may be measured by other processes. Now, crystal orientation measuring step S10 of measuring characteristics with respect to the crystal orientation of the material of the ingot 11 using a laser processing apparatus 2 illustrated in FIG. 2 will be described below. FIG. 2 schematically illustrates, in perspective, the ingot 11 in crystal orientation measuring step S10, and FIG. 3 schematically illustrates, in plan, the ingot 11 in crystal orientation measuring step S10.

As illustrated in FIG. 2, the laser processing apparatus 2 includes a support table 4 for supporting the ingot 11 thereon and a laser beam applying unit 8 for applying a laser beam 12 to the ingot 11 supported on the support table 4. The support table 4 has an upper surface acting as a support surface 6 for supporting the ingot 11 thereon. The support surface 6 has an extremely high level of planarity for highly accurately measuring characteristics with respect to the crystal orientation of the material of the ingot 11. The support table 4 includes, for example, a chuck table for holding the ingot 11 on the support surface 6 under a negative pressure applied to the ingot 11. The laser beam applying unit 8 includes a processing head 10 for emitting a laser beam 12 downwardly toward the ingot 11 on the support table 4. The laser beam applying unit 8 focuses the emitted laser beam 12, which has a wavelength transmittable through the material of the ingot 11, into a focused spot 14 at a predetermined height within the ingot 11. The support table 4 and the processing head 10 of the laser beam applying unit 8 are movable relatively to each other in directions parallel to the support surface 6.

The focused spot 14 is positioned at a position in the ingot 11 that is spaced downwardly a predetermined depth from the face side 11a of the ingot 11, and the laser beam 12 whose wavelength is transmittable through the material, i.e., SiC, of the ingot 11 is applied to the ingot 11 while the ingot 11 and the focused spot 14 are being moved relatively to each other. At this time, the laser beam 12 forms a modified layer 16 in the ingot 11 along the direction the focused spot 14 scans the ingot 11 and cracks developed from the modified layer 16. The modified layer 16 and the cracks jointly make up a region whose strength is reduced, i.e., a reduced-strength region. For example, in crystal orientation measuring step S10, the laser beam 12 is focused into the focused spot 14 while the focused spot 14 is scanning the ingot 11 along a straight line. Then, the direction the focused spot 14 scans the ingot 11 is slightly changed, and the laser beam 12 is focused into the focused spot 14 while the focused spot 14 is scanning the ingot 11 along a straight line. In this manner, the direction the focused spot 14 scans the ingot 11 is changed successively each time the focused spot 14 scans the ingot 11. FIGS. 2 and 3 illustrate a plurality of modified layers 16, indicated by broken lines, formed in the ingot 11.

When the direction in which the focused spot 14 scans the ingot 11 is parallel to the direction in which the second orientation flat 29 to be formed on the ingot 11, i.e., the wafer 21, extends, a reduced-strength region that is free of nodes is formed in the ingot 11. This is because the cracks are considered to be developed from a modified layer 16 along one c-plane. On the other hand, when the direction in which the focused spot 14 scans the ingot 11 is not parallel to the direction in which the second orientation flat 29 to be formed on the ingot 11 extends, a reduced-strength region including nodes is formed in the ingot 11. This is because the focused spot 14 is considered to move across a plurality of c-planes that are in different depthwise positions. Specifically, cracks developed in a c-plane and cracks developed in a different c-plane are considered to be spaced from each other by a step interposed therebetween, which occur as a node in the reduced-strength region. Therefore, by observing modified layers 16 formed in the ingot 11 and confirming how nodes are present in reduced-strength regions formed around the modified layers 16, the direction in which the second orientation flat 29 to be formed in the ingot 11, i.e., the wafer 21, extends can be specified. In other words, characteristics with respect to the crystal orientation of the ingot 11, i.e., the wafer 21, are measured.

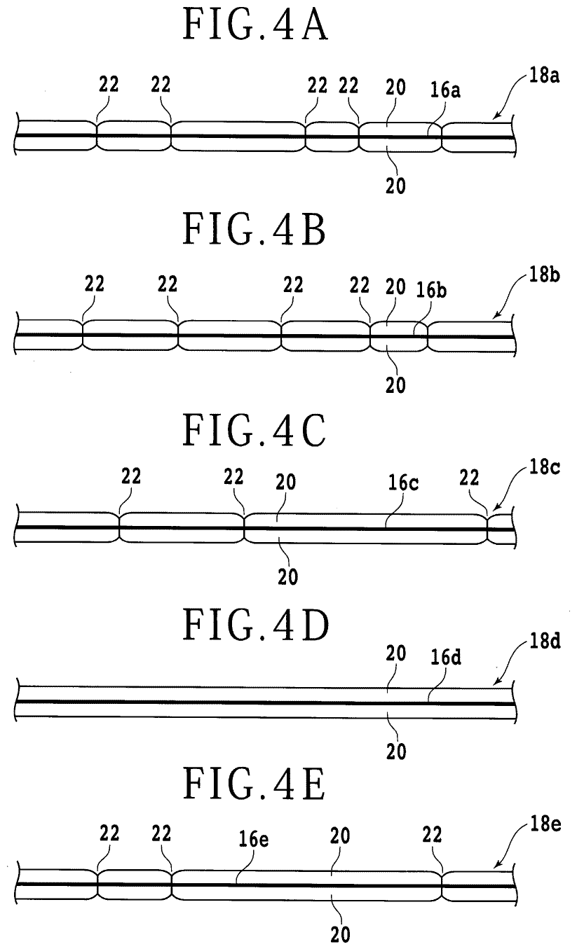

Reduced-strength regions will be described in specific details below. FIG. 3 schematically illustrates, in plan, five modified layers 16a, 16b, 16c, 16d, and 16e, indicated respectively by the broken lines, formed in the ingot 11 by the laser beam 12 applied thereto and extending in different directions. FIGS. 4A through 4E schematically illustrate, in plan, reduced-strength regions 18a, 18b, 18c, 18d, and 18e, respectively, including respective modified layers 16a, 16b, 16c, 16d, and 16e and respective crack-formed regions 20 where cracks are formed.

In the reduced-strength region 18a illustrated in FIG. 4A, nodes 22 are confirmed in the crack-formed region 20 around the modified layer 16a. In other words, the nodes 22 are confirmed in the reduced-strength region 18a. Consequently, it can be seen that the direction in which the focused spot 14 of the laser beam 12 scans the ingot 11 at the time of forming the modified layer 16a in the ingot 11 is not parallel to the direction in which the second orientation flat 29 to be formed on the ingot 11 extends. Similarly, in the reduced-strength regions 18b, 18c, and 18e illustrated respectively in FIGS. 4A, 4B, 4C, and 4E, nodes 22 are confirmed in the crack-formed regions 20 around the modified layers 16b, 16c, and 16e. Consequently, it can be seen that the direction in which the focused spot 14 of the laser beam 12 scans the ingot 11 at the time of forming the modified layers 16b, 16c, and 16e in the ingot 11 is not parallel to the direction in which the second orientation flat 29 to be formed on the ingot 11 extends. On the other hand, in the reduced-strength region 18d illustrated in FIG. 4D, nodes 22 are not confirmed in the crack-formed region 20 around the modified layer 16d. In other words, the nodes 22 are not confirmed in the reduced-strength region 18d. Consequently, it can be seen that the direction in which the focused spot 14 of the laser beam 12 scans the ingot 11 at the time of forming the modified layer 16d in the ingot 11 is parallel to the direction in which the second orientation flat 29 to be formed on the ingot 11 extends.

When crystal orientation measuring step S10 is carried out using the laser processing apparatus 2, the laser beam 12 is applied to the ingot 11 while being moved, i.e., processing-fed, relatively to the ingot 11 along each of a plurality of directions. Each of the directions inclined to an adjacent one through a predetermined angle of 0.5 degrees, for example, by moving and turning the support table 4. Specifically, the focused spot 14 repeatedly scans the ingot 11 along each of different directions that is different from an adjacent one through a predetermined angle of 0.5 degrees, for example. The laser beam 12 may be applied under processing conditions given below. The term “defocus” in the processing conditions refers to a distance by which the focused spot 14 of the laser beam 12 is moved upwardly from the face side 11a of the ingot 11.
Laser beam wavelength: 1064 nm
Repetitive frequency: 80 KHz
Average power output: 3.2 W
Pulse duration: 3 ns
Focused spot diameter: ϕ10 μm
Numerical aperture (NA) of condensing lens: 0.65
Processing feed speed: 150 mm/s
Defocus: 90 μm

According to the process described above, the direction in which the second orientation flat 29 to be formed in the ingot 11, i.e., the wafer 21, extends is specified. In other words, according to the process described above, characteristics with respect to the crystal orientation of the material of the ingot 11, i.e., the wafer 21, are measured. The measured characteristics with respect to the crystal orientation of the material of the ingot 11 are used when marks indicative of the crystal orientation of the material are formed on the wafer 21 subsequently in mark forming step S41, as described later.

A crack-formed region 20, i.e., a reduced-strength region, around a modified layer 16 along the direction specified as the direction in which the second orientation flat 29 to be formed extends may include a few nodes 22. For example, the number of nodes 22 that exist per unit length, e.g., 10 mm, of each of modified layers 16 is measured, and the direction in which the modified layer 16 extends at the time a crack-formed region 20, i.e., a reduced-strength region, where the number of nodes 22 is zero is formed around the modified layer 16, may be regarded as the specified direction. Alternatively, when a plurality of modified layers 16 are formed in the ingot 11 along respective directions that are different from each other, the direction in which the modified layer 16 extends around which a crack-formed region 20 where the number of nodes 22 is the smallest is formed may be specified as the direction in which the second orientation flat 29 to be formed extends. Further alternatively, when a plurality of modified layers 16 are formed in the ingot 11 along respective directions that are different from each other, two of the modified layers 16 are selected around which respective crack-formed regions 20 where the number of nodes 22 is relatively small are formed. A direction that exists between the directions in which the selected modified layers 16 extend may be specified as the direction in which the second orientation flat 29 to be formed extends.

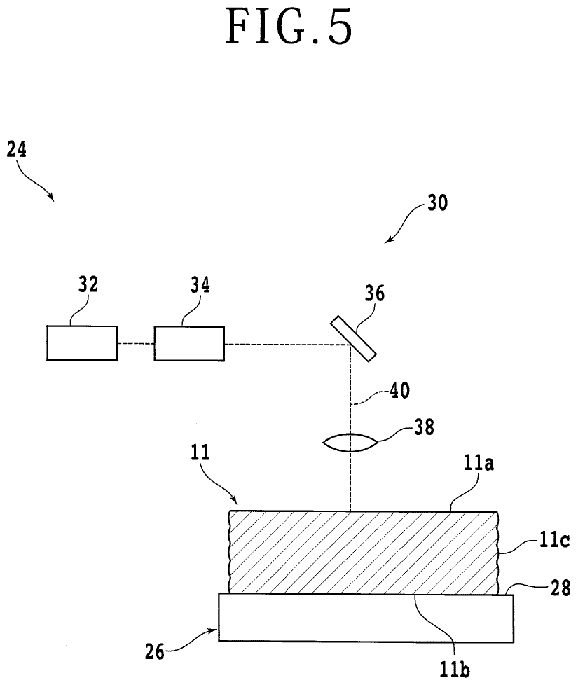

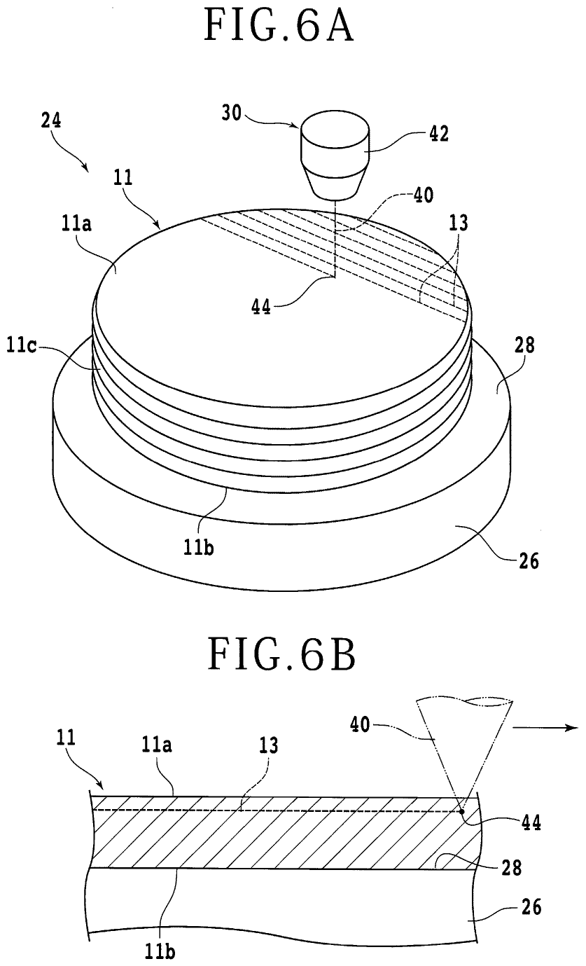

In the wafer manufacturing method according to the present embodiment, separation layer forming step S20 of forming a separation layer within the ingot 11 is carried out before or after crystal orientation measuring step S10. Details of separation layer forming step S20 will be described below. Separation layer forming step S20 is carried out on a laser processing apparatus 24 illustrated in FIGS. 5 and 6A, for example.

As illustrated in FIGS. 5 and 6A, the laser processing apparatus 24 includes a chuck table 26 having a holding surface 28 for holding the ingot 11 under suction thereon and a laser beam applying unit 30 for applying a laser beam 40 to the ingot 11 held on the chuck table 26, thereby to process the ingot 11. The laser beam 40 has a wavelength transmittable through the ingot 11. The chuck table 26 has a suction channel, not depicted, defined therein that has an end fluidly connected to the holding surface 28 and an opposite end fluidly connected to a suction source such as a vacuum pump, for example. When the suction source is actuated, it generates and transmits a negative pressure through the suction channel to the holding surface 28, holding the ingot 11 under suction on the holding surface 28.

FIG. 5 also illustrates an optical system of the laser beam applying unit 30 as a simplest structural example in side elevation. As illustrated in FIG. 5, the laser beam applying unit 30 includes a laser oscillator 32 for emitting a laser beam 40 and an attenuator 34 for adjusting the power output of the laser beam 40. The laser beam applying unit 30 also includes a mirror 36 for reflecting the laser beam 40 from the attenuator 34 and a condensing lens 38 for converging the laser beam 40 reflected by the mirror 36 into a focused spot 44 (see FIG. 6A). However, the laser beam applying unit 30 is not limited to the illustrated optical system. The laser beam applying unit 8 of the laser processing apparatus 2 described above is structurally identical to the laser beam applying unit 30. As illustrated in FIG. 6A, the laser beam applying unit 30 of the laser processing apparatus 24 further includes a processing head 42 in which the optical system is partly or wholly housed. The laser processing apparatus 24 is capable of moving the processing head 42 and the chuck table 26 relatively to each other along directions parallel to the holding surface 28 of the chuck table 26. By thus moving the processing head 42 and the chuck table 26 relatively to each other, the laser processing apparatus 24 can move the focused spot 44 of a laser beam 40 to scan the ingot 11 held on the chuck table 26.

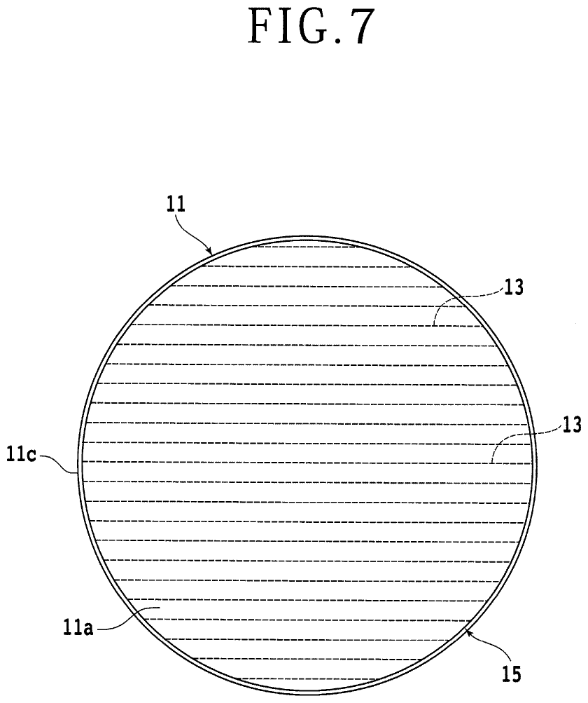

FIG. 6A schematically illustrates the ingot 11 in separation layer forming step S20, and FIG. 6B schematically illustrates, in fragmentary vertical cross section, the ingot 11 in separation layer forming step S20. FIGS. 6A and 6B schematically illustrate the ingot 11 in which modified layers 13 acting as a separation layer are being formed. FIG. 7 schematically illustrates, in plan, the ingot 11 in which the modified layers 13, i.e., the separation layer 15, have been formed.

In separation layer forming step S20, the ingot 11 is placed on the holding surface 28 of the chuck table 26, and the suction source fluidly coupled to the chuck table 26 is actuated to hold the ingot 11 under suction on the holding surface 28. Then, the laser beam applying unit 30 is moved to a position above the ingot 11, and the optical system thereof is adjusted or the height of the laser beam applying unit 30 is adjusted to position the focused spot 44 of the laser beam 40 at a predetermined height.

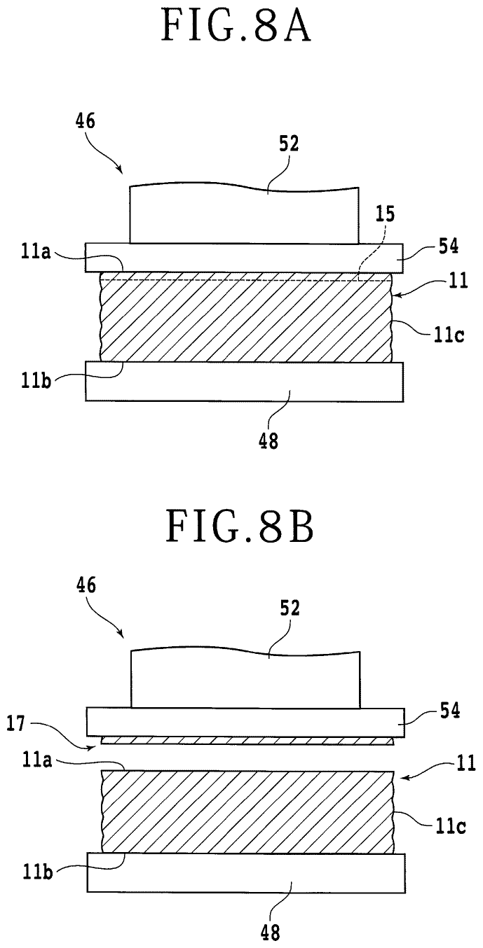

The predetermined height at which the focused spot 44 is positioned refers to a height or vertical position where the laser beam 40 is focused to form the separation layer 15 (see FIG. 8A) at a predetermined height in the ingot 11. The height of the focused spot 44 may not necessarily be the same as the predetermined height in the ingot 11 where the separation layer 15 is to be formed. The separation layer 15 lies in the ingot 11 parallel to the face side 11a of the ingot 11 and allows the ingot 11 is to be severed or divided therealong. The separation layer 15 is spaced from the face side 11a by a distance or depth corresponding to the thickness of the wafer 21 to be fabricated from the ingot 11.

In separation layer forming step S20, the focused spot 44 of the laser beam 40 is positioned at the predetermined height in the ingot 11. Then, while the chuck table 26 and the processing head 42 are being moved relatively to each other, i.e., while the ingot 11 and the focused spot 44 are being moved relatively to each other, the laser beam 40 is applied to the ingot 11. Specifically, in separation layer forming step S20, a process of forming a straight modified layer 13 in the ingot 11 by moving the ingot 11 and the focused spot 44 relatively to each other in a first direction, i.e., a processing-feed direction, and a process of moving the ingot 11 and the focused spot 44 relatively to each other in a second direction, i.e., an indexing-feed direction, are alternately repeated.

In a case where the wafer 21 is made of monocrystalline SiC, the first direction should preferably be a direction perpendicular to the direction in which the off-angle is formed and parallel to the face side 11a, and the second direction should preferably be a direction equal to the direction in which the off-angle is formed and parallel to the face side 11a. If crystal orientation measuring step S10 is carried out before separation layer forming step S20, the first direction and the second direction may be specified on the basis of the characteristics with respect to the crystal orientation of the material obtained in crystal orientation measuring step S10.

When the laser beam 40 is focused into the focused spot 44 in the ingot 11, it forms a modified layer 13 in the vicinity of the focused spot, with cracks, not depicted, being developed from the modified layer 13 that has been formed. When a plurality of modified layers 13 are formed in the ingot 11 along the face side 11a thereof and cracks are developed from each of the modified layers 13 that have been formed, the modified layers 13 and the cracks jointly make up a separation layer 51 in the ingot 11 that lies parallel to the face side 11a. In FIGS. 6A, 6B, and 7, the modified layers 13 formed in the ingot 11 are indicated by the broken lines, and the cracks are omitted from illustration for illustrative purposes. The ingot 11 can easily be severed along the separation layer 15 that acts as separation initiating points.

Conditions under which the laser beam 40 is applied to the ingot 11 are set forth below. In a case where the ingot 11 is a SiC ingot, the laser beam 40 may be applied to the ingot 11 under the conditions set forth below, though the conditions are not restrictive by nature.
Laser beam wavelength: 1064 nm
Repetitive frequency: 60 KHz
Average power output: 1.5 W
Pulse duration: 4 ns
Focused spot diameter: π3 μm
Numerical aperture (NA) of condensing lens: 0.65
Processing-feed speed: 200 mm/s
Indexed distance: 250 to 400 μm
Depth of focused spot from face side: 300 μm

In the wafer manufacturing method according to the present embodiment, separation layer forming step S20 is followed by separating step S30 of applying external forces to the ingot 11 to sever the ingot 11 by impact along the separation layer 15, separating off the wafer 21 from the ingot 11. In separating step S30, for example, ultrasonic vibrations are imposed on the ingot 11 with the separation layer 15 formed therein, thereby separating off the wafer 21 from the ingot 11. However, the ingot 11 may be severed to separate off the wafer 21 by any of various other processes. The wafer 21 is produced from the ingot 11 as a slice separated off the ingot 11 along the separation layer 15 when the ingot 11 is thus severed by the external forces applied thereto.

FIG. 8A schematically illustrates, in vertical cross section, partly in side elevation, the ingot 11 in a first stage of separating step S30, and FIG. 8B schematically illustrates, in vertical cross section, partly in side elevation, the ingot 11 in a second stage of separating step S30. FIGS. 8A and 8B illustrate a separating apparatus 46 used in separating step S30 in side elevation each. The separating apparatus 46 will be described below with reference to FIGS. 8A and 8B. The separating apparatus 46 includes a support table 48 for supporting the ingot 11 placed thereon and a suction pad 54 disposed above the support table 48.

The support table 48 is, for example, a chuck table for holding the ingot 11 under suction thereon, though the support table 48 is not limited to a chuck table. The support table 48 has a suction channel, not depicted, defined therein that is fluidly connected to a suction source, not depicted, such as a vacuum pump, for example. When the suction source is actuated, it generates and transmits a negative pressure through the suction channel to an upper holding surface of the support table 48, holding the ingot 11 under suction on the upper holding surface. The suction pad 54 is mounted on the lower end of a vertically movable support shaft 52. The suction pad 54 has a lower surface acting as a suction surface for holding an object, i.e., the ingot 11, held in contact therewith under suction. The suction pad 54 has a suction channel, not depicted, defined therein that is fluidly connected to a suction source, not depicted, such as a vacuum pump, for example. When the suction source is actuated, it generates and transmits a negative pressure through the suction channel to the suction surface of the suction pad 54, holding the ingot 11 under suction on the holding surface. At least one of the support table 48 or the suction pad 54 houses therein an ultrasonic vibratory unit, not depicted. The ultrasonic vibratory unit includes an ultrasonic transducer such as a Piezo device that produces ultrasonic vibrations when energized.

In the first stage of separating step S30, the ingot 11 in which the separation layer 15 has already been formed is placed on the support table 48. At this time, the reverse side 11b of the ingot 11 faces downwardly and is held in contact with the upper suction surface of the support table 48, and the face side 11a of the ingot 11 is exposed upwardly. Then, the support shaft 52 is lowered toward the support table 48 to bring the lower suction surface of the suction pad 54 into contact with the face side 11a of the ingot 11. Then, in the second stage of separating step S30, the ultrasonic vibratory unit is energized to generate and apply ultrasonic vibrations to the ingot 11. The ultrasonic vibrations applied to the ingot 11 ultrasonically vibrate the ingot 11, severing the ingot 11 along the separation layer 15. Almost at the same time that the ultrasonic vibrations are applied to the ingot 11, the suction source fluidly connected to the lower suction surface of the suction pad 54 is actuated to apply a negative pressure to the face side 11a of the ingot 11, attracting the ingot 11 under suction to the suction pad 54.

The ultrasonic vibrations applied to the ingot 11 to sever the ingot 11 along the separation layer 15. When the suction pad 54 attracting the ingot 11 under suction thereto is lifted, a portion of the ingot 11 that is positioned above the separation layer 15 and leads up to the face side 11a is pulled off by the suction pad 54, leaving the remainder of the ingot 11, i.e., a portion of the ingot 11 that is positioned below the separation layer 15, on the support table 48. FIG. 8B schematically illustrates the manner in which the portion of the ingot 11 that is positioned above the separation layer 15 and leads up to the face side 11a is pulled off by the suction pad 54. The portion of the ingot 11 thus pulled off becomes a wafer 17. In other words, the ingot 11 is severed along the separation layer 15, separating off the portion of the ingot 11 thus pulled off as the wafer 17. The remainder of the ingot 11 left on the support table 48 will be similarly processed to manufacture a next wafer 17 therefrom. Specifically, a new separation layer 15 will be formed at a height in the ingot 11 at a predetermined depth from a newly exposed face side 11a of the ingot 11, and the ingot 11 will be severed along the new separation layer 15, separating off a next wafer 17.

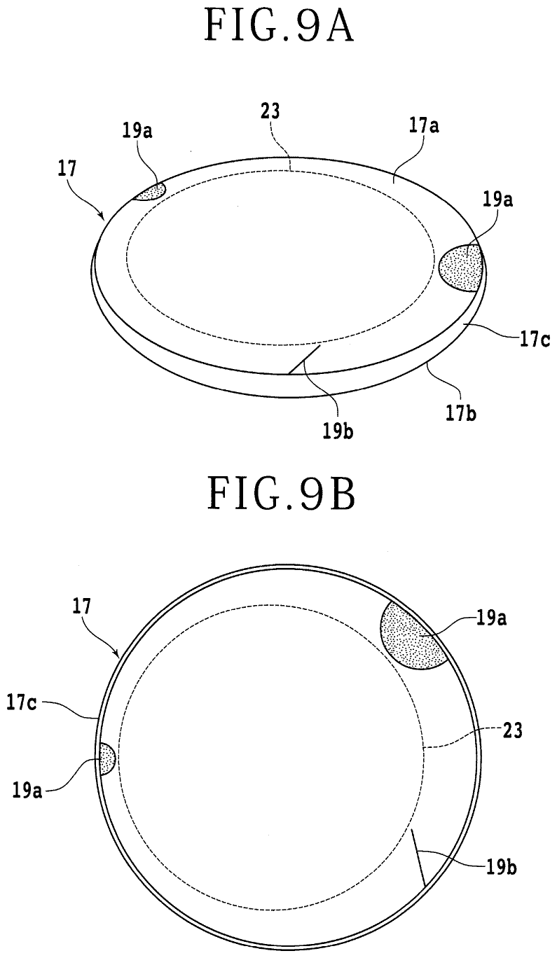

According to the other embodiment of the present invention, the wafer manufacturing method includes inspecting step S31 (see FIG. 12B) after separating step S30 and before outer form shaping step S42. In inspecting step S31, the wafer 17 is inspected to ascertain whether the wafer 17 contains crystal defects or not and to detect the positions of crystal defects, if any. FIG. 9A schematically illustrates, in perspective, the wafer 17 whose outer form has not yet been shaped, and FIG. 9B schematically illustrates, in plan, the wafer 17 whose outer form has not yet been shaped. The ingot 11 that is made of monocrystalline SiC may contain crystal defects occurring during its crystal growth. Therefore, the wafer 17 manufactured from the ingot 11 may contain crystal defects. FIGS. 9A and 9B schematically illustrate the wafer 17 as having crystal defect regions 19a occurring in its parts. In FIGS. 9A and 9B, the crystal defect regions 19a are depicted stippled for illustrative purposes.

When devices are constructed in the crystal defect regions 19a of the wafer 17, the devices may not have desired characteristics. Consequently, it is preferable to remove crystal defect regions, if any, from the wafer 17. In inspecting step S31, the wafer 17 is inspected to check whether the wafer 17 contains crystal defects or not and to detect the positions of crystal defects, if any, in order to remove crystal defect regions subsequently in outer form shaping step S42. Specifically, the crystal defect regions 19a of the wafer 17 are detected by way of either photoluminescence (PL) spectroscopy, an observation using an optical microscope, an observation using an electron microscope such as a scanning electron microscope (SEM) or a scanning transmission electron microscope (STEM), an observation based on X-ray topography, or Raman spectroscopy. However, inspecting step S31 is not limited to these detecting processes, and may detect the crystal defect regions 19a of the wafer 17 by way of other detecting processes. In inspecting step S31, regions of the wafer 17 not suitable for the construction of devices other than the crystal defect regions 19a may be detected. For example, a crack 19b occurring in the wafer 17 may be detected in inspecting step S31.

Outer form shaping step S42 for shaping the outer form of the wafer 17 is carried out after separating step S30. Outer form shaping step S42 should preferably be carried out after inspecting step S31 of the wafer manufacturing method according to the present embodiment. In outer form shaping step S42, the wafer 17 separated off the ingot 11 is processed to remove an unwanted area therefrom. For example, if the wafer 17 has been found as having crystal defects in inspecting step S31, the outer form of the wafer 17 is shaped to remove the crystal defects from the wafer 17 in outer form shaping step S32.

In outer form shaping step S32, a boundary 23 (see FIGS. 9A and 9B) is established between an area to be removed from the wafer 17 and an area to be left in the wafer 17. For example, the boundary 23 is established to delineate the area to be removed that includes the crystal defect regions 19a and the crack 19b. The boundary 23 is set to a circular shape that is as large as possible. Alternatively, the boundary 23 is set to a particular circular shape that is selected according to the standards of wafers used to construct devices thereon. In FIGS. 9A and 9B, the circular boundary 23 thus determined is indicated by a broken line. In outer form shaping step S32, the area of the wafer 17 that is positioned radially outwardly from the circular boundary 23 is removed. For example, the outer form of the wafer 17 is shaped by grinding off the area of the wafer 17 that is positioned radially outwardly from the circular boundary 23 progressively from an outer circumferential edge 17c of the wafer 17, or cutting the wafer 17 along the circular boundary 23, thereby getting rid of the crystal defect regions 19a and the crack 19b. If the area of the wafer 17, separated from the ingot 11, that is positioned radially outwardly from the circular boundary 23 is ground off progressively from the outer circumferential edge 17c, then the efficiency with which to process, i.e., to grind, the wafer 17 is low because the area of the wafer 17 to be ground off is relatively large. Accordingly, it is preferable to shape the outer form of the wafer 17 by cutting the wafer 17 along the boundary 23. The wafer 17 may be cut along the boundary 23 by the laser processing apparatus 24 illustrated in FIGS. 5 and 6A, for example.

Specifically, in outer form shaping step S32, the wafer 17 is placed on the chuck table 26 of the laser processing apparatus 24 and held under suction on the holding surface 28 of the chuck table 26. At this time, a reverse side 17b of the wafer 17 faces downwardly and is held in contact with the holding surface 28 of the chuck table 26, and a face side 17a of the wafer 17 is exposed upwardly. Then, the chuck table 26 and the processing head 42 of the laser beam applying unit 30 are moved relatively to each other in directions parallel to the holding surface 28 to position the processing head 42 above a point on the boundary 23. Thereafter, while the laser beam 40 is being applied to the wafer 17 with the focused spot 44 positioned at a predetermined height between the face side 17a and the reverse side 17b of the wafer 17, the chuck table 26 and the processing head 42 are circularly moved relatively to each other to move the focused spot 44 in a circular path along the boundary 23.

Conditions under which the laser beam 40 is applied to the wafer 17 are set forth below. In a case where the wafer 17 is a SiC ingot, the laser beam 40 may be applied to the ingot 11 under the conditions set forth below, though the conditions are not restrictive by nature.
Laser beam wavelength: 532 nm
Repetitive frequency: 60 kHz
Average power output: 3.0 W
Pulse duration: 10 ns
Numerical aperture (NA) of condensing lens: 0.6
Processing-feed speed: 100 mm/s
Depth of focused spot from face side: 150 μm

When the laser beam 40 is applied to the wafer 17 along the boundary 23, the focused spot 44 forms a modified layer acting as division initiating points in the wafer 17 along the boundary 23. Thereafter, external forces are applied to the wafer 17, breaking the wafer 17 by impact along the modified layer thereby to separate off the area of the wafer 17 that is positioned radially outwardly from the circular boundary 23, leaving a wafer 21 (see FIG. 10A) from which the unwanted area has been removed. That is the wafer 21 whose outer form has been shaped is obtained. As described above, if crystal defects and other faults are detected in the wafer 17 in inspecting step S31, those crystal defects and other faults are removed by shaping the outer form of the wafer 17 in outer form shaping step S42. Outer form shaping step S42 may not be carried out by the laser processing apparatus 24. Rather, outer form shaping step S42 may be carried out by a cutting apparatus, not depicted, that has an annular cutting blade having a circular cutting edge for cutting workpieces. If such a cutting apparatus is used to shape the outer form of the wafer 17, then the cutting blade cuts into the wafer 17 along the boundary 23, forming a cut groove in the wafer 17 along the boundary 23.

It has been the usual practice in the art to manufacture a plurality of wafers 17 from the ingot 11 by separating them off from the ingot 11. In those wafers 17, crystal defect regions 19a and cracks 19b may not necessarily occur in the same positions and have the same sizes. Therefore, different boundaries 23 are individually established on the respective wafers 17, and the wafers 17 are cut along the individually established different boundaries 23. In the wafer manufacturing methods according to the present embodiment, different boundaries 23 can be optimally established on the wafers 17, and the wafers 17 can be cut along the different optimum boundaries 23 thereon. Consequently, a plurality of wafers 21 whose outer forms have been shaped under optimum conditions are manufactured.

According to a known practice in the art, an ingot 11 is ground into a cylindrical shape and then sliced into a plurality of wafers 17. Before the wafers are cut from the ingot 11, a common boundary is established on the ingot 11 such that unwanted areas outside of the boundary can be removed from all the wafers 17. Thereafter, the ingot 11 is ground into a cylindrical shape progressively from an outer circumferential edge thereof radially outside of the boundary. One problem with this process is that a useful area of a wafer 17 may overlap an unwanted area of another wafer and the overlapping useful area is removed when the unwanted area is removed at the time the ingot 11 is ground into the cylindrical shape. In other words, the wafer fabricating process fails to make full use of the material of the ingot. In the wafer manufacturing method according to the present embodiment, by contrast, each of the wafers 17 fabricated from the ingot 11 has a boundary 23 individually established to suit its own defects for maximizing a useful area left on the wafer 17. Stated otherwise, it is not necessary to waste a useful area of a wafer 17 for the reason that it overlaps an unwanted area of another wafer 17. Therefore, the material of the ingot 11 can be exploited to the maximum extent possible.

Moreover, inasmuch as an ingot 11 is far thicker than each of the wafers 17 produced therefrom, it is difficult to cut the ingot 11 using the laser processing apparatus 24 and the cutting apparatus. Therefore, a dedicated cylindrical grinding apparatus has to be used to shape the outer form of the ingot 11. In the wafer manufacturing method according to the present embodiment, however, the outer form of the wafer 17 can be shaped by the laser processing apparatus 24 and the cutting apparatus that can be used in various applications. Accordingly, wafers 21 whose outer forms have been shaped and that have their outer circumferential edge 21c neatly finished can be fabricated easily and inexpensively. The wafer manufacturing method according to the present embodiment is capable of highly efficiently fabricating wafers 21 that have shaped outer forms and that are of high quality.

The outer circumferential edge 17c of the wafer 17 may have surface irregularities that have occurred during the fabrication of the ingot 11. In the wafer manufacturing method according to the present embodiment, the outer circumferential edge 17c of the wafer 17 that may have such surface irregularities is removed in outer form shaping step S32. In other words, when outer form shaping step S32 is carried out, the unwanted area of the wafer 17 is removed and the outer form of the wafer 17 is shaped. Moreover, outer form shaping step S32 may be carried out solely for the purpose of removing surface irregularities that have occurred on the outer circumferential edge 17c during the fabrication of the ingot 11. In this case, inspecting step S31 for inspecting the wafer 17 separated from the ingot 11 may not be carried out. Furthermore, it is preferable to carry out outer form shaping step S32 even if crystal defects and other faults are not confirmed on the wafer 17 in inspecting step S31.

In the wafer manufacturing method according to the present embodiment, mark forming step S41 may be carried out instead of or after outer form shaping step S42 after separating step S30. In mark forming step S41, a mark indicative of the crystal orientation of the material of the wafers 17 and 21 is formed on the wafers 17 and 21. The mark indicative of the crystal orientation includes a notch or an orientation flat, for example. FIG. 10A schematically illustrates, in plan, the wafer 21 on which marks have not yet been formed, and FIG. 10B schematically illustrates, in plan, the wafer 21 with the marks formed thereon. In a case where the wafer 21 is a monocrystalline SiC wafer, two marks are formed on the wafer 21 in mark forming step S41. Specifically, a first orientation flat 27 and a second orientation flat 29 lying perpendicularly to the first orientation flat 27 are formed as the respective two marks on the wafer 21.

The positions and shapes on the wafers 17 and 21 of the marks formed thereon in mark forming step S41 may be determined on the basis of the characteristics with respect to the crystal orientation of the material measured in crystal orientation measuring step S10. In this case, the orientation of the wafers 17 and 21 need to be continuously specified until the marks are formed on the wafers 17 and 21 such that the characteristics with respect to the crystal orientation of the material will not lose their significance after the wafers 17 and 21 are separated from the ingot 11 in separating step S30. In other words, even after the wafer 17 has been separated from the ingot 11, it is necessary to keep on specifying which orientation the wafer 17 took in the ingot 11 before it was separated from the ingot 11.

Moreover, even in a case where the wafer 21 is obtained from the wafer 17 by cutting the wafer 17 along the boundary 23 in outer form shaping step S42, the orientation of the wafer 21 needs to be specified until the marks are formed on the wafer 21. In other words, even after the wafer 21 has been cut out of the wafer 17, it is necessary to keep on specifying which orientation the wafer 17 took in the ingot 11 when the wafer 21 was included in the ingot 11.

In mark forming step S41, the marks, i.e., the first orientation flat 27 and the second orientation flat 29, are formed on the wafers 17 and 21 by processing the outer circumferential portions of the wafers 17 and 21 with a laser beam, for example. In FIG. 10A, projected cutting locations 25 established on the wafers 17 and 21 to indicate where the marks are to be formed are indicated by broken lines. In mark forming step S41, the wafers 17 and 21 are cut at the projected cutting locations 25, thereby forming the marks thereon. For example, the wafers 17 and 21 are cut by the laser processing apparatus 24. The process of cutting the wafers 17 and 21 with the laser beam 40 is the same as the laser beam process carried out in outer form shaping step S42. Therefore, the process of cutting the wafers 17 and 21 at the projected cutting locations 25 by the laser processing apparatus 24 will be omitted from detailed description.

When mark forming step S41 is carried out, the marks, i.e., the first orientation flat 27 and the second orientation flat 29, that are indictive of the crystal orientation of the material of the wafers 17 and 21 are formed on the wafers 17 and 21. For cutting the wafers 17 and 21, a cutting apparatus, not depicted, that has an annular cutting blade having a circular cutting edge for cutting workpieces may be used instead of the laser processing apparatus 24. The wafer manufacturing method according to the present embodiment is capable of forming the marks on the outer circumferential portions of the wafers 17 and 21 using various processing apparatus such as the laser processing apparatus 24 and the cutting apparatus that are versatile in use. Therefore, the wafers 17 and 21 having the marks indicative of the crystal orientation of the material can be obtained with ease and at low cost. Accordingly, wafer manufacturing method according to the present embodiment can manufacture high-quality wafers 17 and 21 with marks highly efficiently.

In the wafer manufacturing methods according to the embodiments of the present invention, a separation layer 15 is formed in an ingot 11, and wafers 17 and 21 are produced from the ingot 11 by severing the wafer 17 along the separation layer 15. Thereafter, marks indicative of the crystal orientation of the material of the wafers 17 and 21 are formed on the wafers 17 and 21, and the outer forms of the wafers 17, 21 are shaped. When the individual wafers 17 and 21 are processed, they undergo a smaller processing load than when the ingot 11 is processed. Facilities used to process the individual wafers 17 and 21 are smaller in scale, dedicated facilities do not need to be used, and general-purpose facilities can be used, to process the individual wafers 17 and 21. Moreover, processing conditions can be selected in detail to process the wafers 17 and 21 appropriately to suit individual states thereof, thereby processing the wafers 17 and 21 to a nicety. Consequently, the cost required to manufacture the wafers 17 and 21 can be reduced, and the wafers 17 and 21 can be manufactured with high quality and high productivity.

The present invention is not limited to the embodiments described above, and various changes and modifications may be made in the embodiments. For example, according the above embodiments, the two orientation flats 27 and 29 are formed as marks indicative of the crystal orientation of the material of the wafers 17 and 21 on the wafers 17 and 21 in mark forming step S41. However, the present invention is not limited to such details. According to the present invention, a single mark may be formed on the wafers 17 and 21 in mark forming step S41, and a mark or marks formed on the wafers 17 and 21 may be a recess or recesses referred to as a notch or notches.

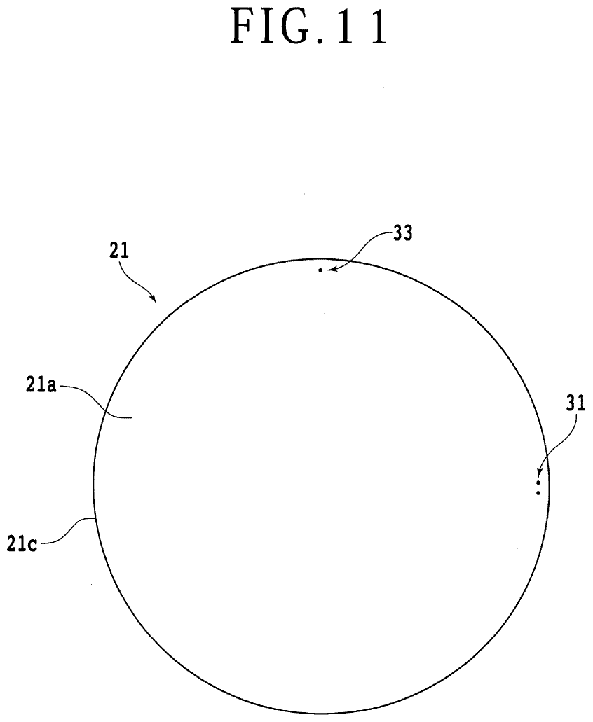

In mark forming step S41, dot-shaped marks may be formed as marks indicative of the crystal orientation of the material of the wafers 17 and 21 on the wafers 17 and 21 in mark forming step S41. FIG. 11 schematically illustrates, in plan, the wafer 21 on which two kinds of marks 31 and 33, i.e., first and second marks 31 and 33, according to a modification are formed. The first mark 31 is formed instead of the first orientation flat 27 (see FIG. 10B) on the wafer 21. The second mark 33 is formed instead of the second orientation flat 29 (see FIG. 10B) on the wafer 21. The first mark 31 and the second mark 33 that are formed on the wafer 21 are distinguished from each other by the number of dots that make up the first mark 31 and the second mark 33.

For example, the first mark 31 is made up of two dots arrayed along the direction in which the first orientation flat 27 extends providing the first orientation flat 27 is formed on the wafer 21. Specifically, a straight line interconnecting the midpoint between the two dots of the first mark 31 and the center of the wafer 21 is perpendicular to the direction in which the first orientation flat 27 extends. Therefore, the crystal orientation that is the same as the crystal orientation indicated by the first orientation flat 27 is indicated by the first mark 31. The second mark 33 is made up of a single dot. A straight line interconnecting the dot of the second mark 33 and the center of the wafer 21 is perpendicular to the direction in which the second orientation flat 29 extends providing the second orientation flat 29 is formed on the wafer 21. Therefore, the crystal orientation that is the same as the crystal orientation indicated by the second orientation flat 29 is indicated by the second mark 33.

Each of the two dots of the first mark 31 and the single dot of the second mark 33 is made up of a circular dot-shaped modified region having a diameter of 3 mm. The two dots, i.e., the two modified regions, of the first mark 31 are spaced from each other by a distance of 5 mm. The two dots, i.e., the two modified regions, of the first mark 31 and the single dot, i.e., the single modified region, of the second mark 33 are positioned approximately 5 mm radially inwardly from the outer circumferential edge 21c of the wafer 21.

The dots, i.e., the modified regions, of the first mark 31 and the dot, i.e., the modified region, of the second mark 33 are formed on the wafer 21 by a laser beam process carried out using the laser processing apparatus 24, for example. Conditions under which the laser beam 40 is applied to the wafer 21 are set forth below. The focused spot 44 of the laser beam 40 is positioned on the face side 21a of the wafer 21. In other words, the depth of the focused spot 44 is 0 μm. The conditions given below are not restrictive by nature.
Laser beam wavelength: 1064 nm
Repetitive frequency: 60 kHz
Average power output: 0.3 W
Pulse duration: 4 ns
Focused spot diameter: ϕ3 μm
Numerical aperture (NA) of condensing lens: 0.65

In a case where the marks 31 and 33 made up of dot-shaped modified regions are formed on the face side 21a of the wafer 21, the amount of material lost from the wafer 21 is far smaller than in a case where the orientation flats 27 and 29 are formed on the wafer 21. Therefore, the material of the wafer 21 can be used more efficiently to form more devices in the wafer 21, so that device chips can be manufactured from the wafer 21 more efficiently. Moreover, in a case where the marks 31 and 33 made up of dot-shaped modified regions are formed on the face side 21a of the wafer 21, the amount of work done on the wafer 21 is minimized. Consequently, the marks 31 and 33 made up of dot-shaped modified regions are formed on the wafer 21 easily and efficiently, resulting in an increase in the efficiency with which to manufacture the wafer 21.

According to the embodiment illustrated in FIG. 12A, before separating step S30, crystal orientation measuring step S10 is carried out to measure characteristics with respect to the crystal orientation of the material from the shape of the reduced-strength region that has been formed by applying the laser beam 12 to the ingot 11, as illustrated in FIG. 2. However, the wafer manufacturing method according to the present invention is not limited to such details. In crystal orientation measuring step S10, characteristics with respect to the crystal orientation of the material may be acquired by measurements based on XRD. Moreover, crystal orientation measuring step S10 may be carried out after separating step S30, and characteristics with respect to the crystal orientation of the material of the wafers 17 and 21, instead of the ingot 11, may be measured.

For example, in crystal orientation measuring step S10, characteristics with respect to the crystal orientation of the material of the wafers 17 and 21 may be acquired by measurements based on X-ray diffraction (XRD). Furthermore, for example, in crystal orientation measuring step S10, characteristics with respect to the crystal orientation of the material may be measured from the shape of the reduced-strength region that has been formed by applying the laser beam 12 to the wafers 17 and 21 instead of the ingot 11. In other words, in crystal orientation measuring step S10, characteristics with respect to the crystal orientation of the material of either the ingot 11 or the wafers 17 and 21 are measured. The material whose crystal orientation is to be measured refers to the material of the ingot 11 or the material of the wafers 17 and 21 separated from the ingot 11. Stated otherwise, the material of the ingot 11 is the same as the material of the wafers 17 and 21.

The reduced-strength regions formed in the ingot 11 or the wafers 17 and 21 by applying the laser beam 12 thereto in crystal orientation measuring step S10 may be disruptive to subsequent steps if they remain as they are in the ingot 11 or the wafers 17 and 21. For example, if the reduced-strength regions remain in the ingot 11, then they tend to obstruct the formation of the separation layer 15 by the laser beam 40 in separation layer forming step S20, or to act as points that start breaking the ingot 11 in separating step S30. If the reduced-strength regions remain in the wafers 17 and 21, then they are liable to cause problems at the time devices are formed on the wafers 17 and 21 and device chips are fabricated by dividing the wafers 17 and 21. In the wafer manufacturing method according to the present invention, crystal orientation measuring step S10 may be followed by a removing step of grinding or polishing the ingot 11 or the wafers 17 and 21 to remove the reduced-strength regions. In the removing step, the ingot 11 is ground or polished from the face side 11a to remove the reduced-strength regions. In the removing step, alternatively, the wafers 17 and 21 are ground or polished from the face sides 17a and 21a to remove the reduced-strength regions.

In the wafer manufacturing method according to the present invention, the ingot 11 or the wafers 17 and 21 may be ground or polished for purposes other than removing the reduced-strength regions, or may be ground or polished while no reduced-strength regions are present in the ingot 11 or the wafers 17 and 21. For example, the face side 11a of the ingot 11 or the face sides 17a and 21a of the wafers 17 and 21 may be ground or polished for planarization.

In mark forming step S41, the positions and shapes on the wafers 17 and 21 of the marks formed thereon may be determined on the basis of the characteristics measured and acquired in crystal orientation measuring step S10. However, the present invention is not limited to such details.

For example, the characteristics with respect to the crystal orientation of the material of the ingot 11 may have been measured and acquired in advance before the wafer manufacturing method according to the embodiment illustrated in FIG. 12A. In this case, in mark forming step S41, the positions and shapes on the wafers 17 and 21 of the marks formed thereon may be determined on the basis of the characteristics with respect to the crystal orientation of the material that have been measured and acquired in advance. In other words, crystal orientation measuring step S10 may not be carried out in wafer manufacturing method according to the embodiment illustrated in FIG. 12A. According to the present invention, marks indicative of the crystal orientation of the material of the ingot 11 may have originally been formed on the ingot 11 before the ingot 11 is processed. When the wafers 17 and 21 are separated from the ingot 11, the wafers 17 and 21 having the marks are obtained from the ingot 11. According to the present invention, therefore, crystal orientation measuring step S10 and mark forming step S41 may not be carried out in the wafer manufacturing method illustrated in FIG. 12A.

In summary, the wafer manufacturing method according to one of the embodiments of the present invention includes, as illustrated in FIG. 12A, crystal orientation measuring step S10, separation layer forming step S20, separating step S30, and mark forming step S41. The wafer manufacturing method according to the other embodiment of the present invention includes, as illustrated in FIG. 12B, separation layer forming step S20, separating step S30, an inspecting step S31, and outer form shaping step S42.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of manufacturing a wafer from an ingot, comprising:
a separation layer forming step of positioning a focused spot of a laser beam transmittable through the ingot in the ingot and applying the laser beam to the ingot to form a separation layer in the ingot while moving the ingot and the focused spot relatively to each other;
after the separation layer forming step, a separating step of applying external forces to the ingot to sever the ingot along the separation layer that acts as a separation initiating point, thereby separating a piece of the ingot as the wafer off from the ingot; and
after the separating step, a mark forming step of forming a mark indicative of a crystal orientation of a material of the wafer on the wafer.

2. The method of manufacturing a wafer according to claim 1, further comprising:
before the separating step, a crystal orientation measuring step of measuring characteristics with respect to the crystal orientation of the material, wherein
the mark forming step includes determining a position and a shape on the wafer of the mark formed on the wafer in the mark forming step, on a basis of the characteristics measured in the crystal orientation measuring step.

3. The method of manufacturing a wafer according to claim 1, wherein the mark forming step includes processing an outer circumferential portion of the wafer with a laser beam to form the mark on the wafer.

4. A method of manufacturing a wafer from an ingot, comprising:
a separation layer forming step of positioning a focused spot of a laser beam transmittable through the ingot in the ingot and applying the laser beam to the ingot to form a separation layer in the ingot while moving the ingot and the focused spot relatively to each other;
after the separation layer forming step, a separating step of applying external forces to the ingot to sever the ingot along the separation layer that acts as a separation initiating point, thereby separating a piece of the ingot as the wafer off from the ingot; and
after the separating step, an outer form shaping step of shaping an outer form of the wafer.

5. The method of manufacturing a wafer according to claim 4, further comprising:
after the separating step, a mark forming step of forming a mark indicative of a crystal orientation of a material of the wafer on the wafer.

6. The method of manufacturing a wafer according to claim 5, further comprising:
before the separating step, a crystal orientation measuring step of measuring characteristics with respect to the crystal orientation of the material, wherein
the mark forming step includes determining a position and a shape on the wafer of the mark formed on the wafer in the mark forming step, on a basis of the characteristics measured in the crystal orientation measuring step.

7. The method of manufacturing a wafer according to claim 4, further comprising:
after the separating step but before the outer form shaping step, an inspecting step of inspecting the wafer to ascertain whether the wafer contains a crystal defect or not and to detect a position of a crystal defect, if any, wherein,
if it is ascertained that the wafer has the crystal defect in the inspecting step, the outer form shaping step includes removing the crystal defect by shaping the outer form of the wafer.
